(19) United States
(12) Patent Application Publication
(10) Pub. No.: US 2009/0127563 A1
(43) Pub. Date: May 21, 2009

(54) THIN FILM TRANSISTOR ARRAY PANEL AND MANUFACTURING METHOD THEREOF

(76) Inventors: Ju-Han BAE, Suwon-si (KR); Jang-Kyum Kim, Seoul (KR)

Correspondence Address: Haynes and Boone, LLP;IP Section, 2323 Victory Avenue, SUITE 700, Dallas, TX, 75219, US

(21) Appl. No.: 12/256,380

(22) Filed: Oct. 22, 2008

(30) Foreign Application Priority Data
Nov. 16, 2007 (KR) 10-2007-0117484

(51) Int. Cl. H01L 33/00; H01L 51/56

(52) U.S. Cl. 257/72; 438/29; 257/E33.053; 257/E51.019

(57) ABSTRACT

According to an embodiment, the method of manufacturing a thin film transistor array panel includes forming a gate wire, a data wire, and a thin film transistor on a substrate and depositing an organic material layer on the gate wire, the data wire, and the thin film transistor. The method further includes forming an optical pattern on the upper surface of the organic material layer, depositing a reflecting electrode layer on the organic material layer, etching the reflecting electrode layer, etching the organic material layer after etching the reflecting electrode layer, and forming a pixel electrode on the reflecting electrode layer. Accordingly, the optical pattern on the upper surface of organic material may be transcribed to the reflecting electrode layer without damage and with clarity.

### CROSS-REFERENCE TO RELATED APPLICATION

This application claims priority to and the benefit of Korean Patent Application No. 10-2007-0117484 filed in the Korean Intellectual Property Office on Nov. 16, 2007, the entire contents of which are incorporated herein by reference.

### BACKGROUND

1. Field of the Invention

The present invention relates generally to a thin film transistor array panel and a manufacturing method thereof. In particular, the present invention for one or more embodiments relates to the thin film transistor array panel and the manufacturing method thereof using an imprint process and having a reflecting electrode with minute optical patterns.

2. Description of the Related Art

Generally, a liquid crystal display (LCD) includes two display panels arranged such that their surfaces, provided with field generating electrodes, face each other, with a liquid crystal material is provided between the two display panels. In a typical LCD, liquid crystal molecules are moved by an electric field generated by applying a voltage to the two electrodes, and a desired image is obtained by controlling the transmittance of light that varies depending on the movement of the liquid crystal molecules.

However, because the LCD is a non-emissive device, a light source is required. The typical LCD may be classified as a transmissive type or a reflective type in accordance with the type of the light source.

In a transmissive type of LCD, light emitted from a backlight, as a light source that is attached to the rear surface of the liquid crystal panel, is incident to the liquid crystal layer such that light transmittance is controlled according to an arrangement of liquid crystal molecules to display colors. With a backlight source, the transmissive type of LCD is adapted to generate bright images that may be displayed in a dark environment. However, the transmissive type of LCD consumes large amounts of power due to the back light source.

In a reflective type of LCD, natural external light or artificial light is reflected, and the light transmittance is controlled according to arrangement of the liquid crystal molecules. Because the reflective type of LCD depends on natural external light or external artificial light to display images, viewing images in a dark environment may be difficult. However, the reflective type of LCD consumes less power in comparison to the transmissive type of LCD.

Another type of LCD includes a transflective type of LCD that selects between a reflection mode and a transmissive mode to display images. The transflective type of LCD provides a reflection region and a transmission region in a single pixel area. In general, a reflecting electrode is provided in the reflection region, and a pixel electrode made of a transparent material is provided in the transmission region. In some instances, the reflecting electrode includes a lens shape to improve reflection efficiency. Typically, the lens shape is difficult to form by a photolithography process using a slit mask, and thus, the lens shape may be formed with an imprint process using a mold.

However, this imprint process typically requires a long period of time to align an imprint mold on the reflection region. As such, since the imprint mold may have the same size as the reflection region, which varies depending on the size of the substrate, different imprint molds are necessary and manufactured according to the size of the substrates, which may increase manufacturing costs.

### SUMMARY

One or more embodiments of the present disclosure provide a thin film transistor array panel and a manufacturing method thereof for which the manufacturing cost of an imprint mold and process time may be reduced, when the reflecting electrode in the reflection region is formed through the imprint process.

According to one embodiment of the present disclosure, a thin film transistor array panel includes a gate wire; a data wire intersecting the gate wire; a thin film transistor connected to the gate wire and the data wire; and an imprint layer disposed on the gate wire, the data wire, and the thin film transistor. The imprint layer includes a contact hole exposing a portion of the thin film transistor. The thin film transistor array panel includes a reflecting electrode disposed on the imprint layer. The reflecting electrode includes planar boundaries substantially matching with planar boundaries of the imprint layer or narrower planar boundaries than the imprint layer. The thin film transistor array panel includes a pixel electrode having a first portion disposed on the reflecting electrode, wherein the pixel electrode is connected to the thin film transistor through the contact hole.

In various implementations, the thin film transistor array panel may include a passivation layer disposed between the thin film transistor and the imprint layer. The imprint layer may include an optical pattern of an embossing enclosed shape, such as a concave mirror shape on its upper surface. The pixel electrode may include a second portion not overlapping the reflecting electrode. The imprint layer may include a portion disposed under the second portion of the pixel electrode. The thin film transistor may include a drain electrode connected to the pixel electrode, and the thin film transistor array panel may include a storage electrode overlapping the drain electrode. The storage electrode may overlap the reflecting electrode.

According to one embodiment of the present disclosure, a method for manufacturing a thin film transistor array panel includes forming a gate wire, a data wire, and a thin film transistor on a substrate; depositing an organic material layer on the gate wire, the data wire, and the thin film transistor; and forming an optical pattern on an upper surface of the organic material layer. The method of manufacturing includes depositing a reflecting electrode layer on the organic material layer; etching the reflecting electrode layer; etching the organic material layer after etching the reflecting electrode layer; and forming a pixel electrode on the reflecting electrode layer.

In various implementations, the pixel electrode may include a first portion overlapping the reflecting electrode and a second portion not overlapping the reflecting electrode. The organic material layer may be disposed under the first and second portions of the pixel electrode. The method may include forming a passivation layer on the gate wire, the data wire, and the thin film transistor, and under the organic material layer. The organic material layer may be etched to have substantially the same planar shape as the reflecting electrode. The etching of the reflecting electrode layer and the etching of the organic material layer may be executed by a single photolithography step. The forming of the optical pattern may include aligning an imprint mold on the organic material layer and imprinting the organic material layer with the imprint mold.

### BRIEF DESCRIPTION OF THE DRAWINGS

FIG. 1 is a layout view of a thin film transistor array panel according to an exemplary embodiment of the present disclosure.

FIG. 2 is a cross-sectional view of the thin film transistor array panel shown in FIG. 1 taken along the line II-II.

FIG. 3 is a layout view of the thin film transistor array panel in an intermediate process of manufacturing the thin film transistor array panel shown in FIGS. 1 and 2 according to an exemplary embodiment of the present disclosure.

FIG. 4 is a cross-sectional view of the thin film transistor array panel shown in FIG. 3 taken along the line IV-IV.

FIG. 5 is a cross-sectional view of a following step of the thin film transistor array panel shown in FIG. 3 and FIG. 4.

FIG. 6 is a layout view of the thin film transistor array panel in an intermediate process of manufacturing the thin film transistor array panel shown in FIGS. 1 and 2 according to one embodiment of the present disclosure.

FIG. 7 is a cross-sectional view of the thin film transistor array panel shown in FIG. 6 taken along the line VII-VII.

FIG. 8 is a layout view of the thin film transistor array panel in an intermediate process of manufacturing the thin film transistor array panel shown in FIGS. 1 and 2 according to one embodiment of the present disclosure.

FIG. 9 is a cross-sectional view of the thin film transistor array panel shown in FIG. 8 taken along the line IX-IX.

FIG. 10 is a cross-sectional view of a following step of the thin film transistor array panel shown in FIG. 8 and FIG. 9.

FIG. 11 is a layout view of the thin film transistor array panel in an intermediate process of manufacturing the thin film transistor array panel shown in FIGS. 1 and 2 according to one embodiment of the present disclosure.

FIG. 12 is a cross-sectional view of the thin film transistor array panel shown in FIG. 11 taken along the line XII-XII.

FIGS. 13 to 19 are cross-sectional views sequentially showing the manufacturing method of the thin film transistor array panel shown in FIGS. 11 and 12.

FIGS. 20 to 22 are cross-sectional views sequentially showing the thin film transistor array panel in the manufacturing process of the thin film transistor array panel according to another exemplary embodiment of the present disclosure.

FIG. 23 is a layout view of a thin film transistor array panel according to another exemplary embodiment of the present disclosure.

FIG. 24 is a cross-sectional view of the thin film transistor array panel shown in FIG. 23 taken along the line XXIV-XXIV.

### DETAILED DESCRIPTION

The present disclosure will be described more fully hereinafter with reference to the accompanying drawings, in which various embodiments of the disclosure are described and shown. It should be appreciated by those skilled in the art that the described embodiments of the present disclosure may be modified in various different ways without departing from the spirit or scope of the present disclosure.

In reference to the drawings, the thickness of layers, films, panels, regions, etc. may be exaggerated for clarity. Like reference numerals refer to like elements throughout the specification. When it is said that any part, such as a layer, film, area, or plate is positioned on another part, it means the part is directly on the other part or above the other part with at least one intermediate part. In contrast, when an element is referred to as being “directly on” another element, there are no intervening elements present.

### Exemplary Embodiment

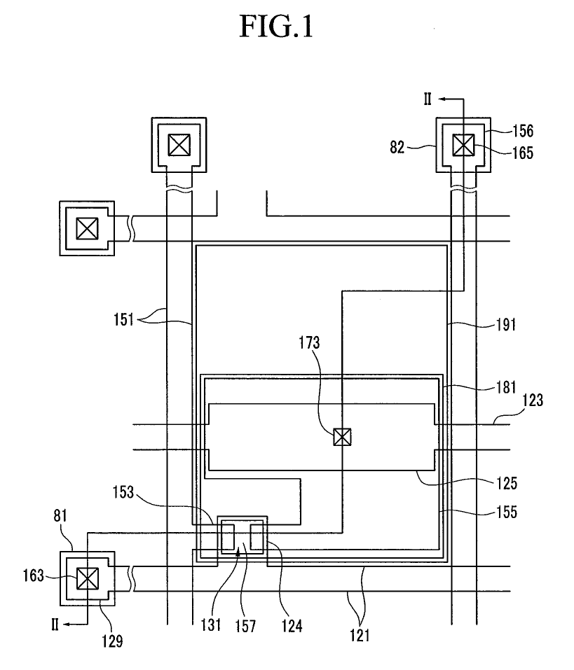

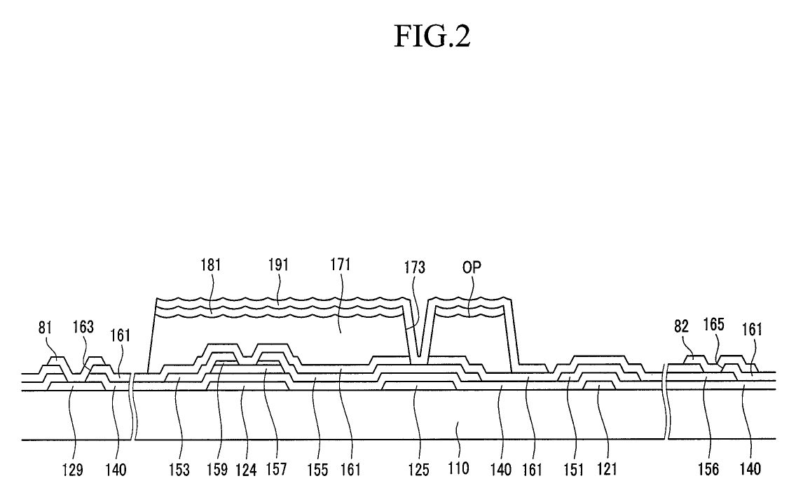

A thin film transistor array panel according to an exemplary embodiment of the present disclosure will now be described in detail with reference to FIGS. 1 and 2. In particular, FIG. 1 is a layout view of a thin film transistor array panel according to an exemplary embodiment of the present disclosure, and FIG. 2 is a cross-sectional view of the thin film transistor array panel shown in FIG. 1 taken along the line II-II.

As shown in FIGS. 1 and 2, a display device according to the present exemplary embodiment includes a substrate 110, gate wires 121, data wires 151, thin film transistors 131, a passivation layer 161, reflecting electrodes 181, pixel electrodes 191, contact assistants 81 and 82, and an imprint layer 171. The substrate 110 comprises an insulating substrate, and other film structures are formed thereon. In the present exemplary embodiment, a glass substrate is used as the substrate 110.

In one implementation, the gate wires 121 supply scanning signals transmitted from a driving circuit (not shown) to the thin film transistors 131. The gate wires 121 are arranged with a uniform interval therebetween and are parallel to each other, and determine the transverse boundary of pixel areas.

The data wires 151 are insulated from and intersect the gate wires 121. In particular, the data wires 151 and the gate wires 121 cross each other substantially with a right angle. The data wires 151 determine the longitudinal boundary of the pixel areas, and thus the gate wires 121 and the data wires 151 define the pixel areas. On the other hand, the data wires 151 carry pixel signals transmitted from a driving circuit, which in turn are applied to the thin film transistors 131.

Next, as shown in FIG. 1, the thin film transistors 131 are disposed adjacent to neighboring intersections of the gate wires 121 and the data wires 151, and the thin film transistors 131 are connected to the gate wires 121 and the data wires 151. The thin film transistors 131 are switched by scanning signals transmitted by the gate wires 121 to transmit the pixel signals from the data wires 151 to the pixel electrodes 191. In the present exemplary embodiment, as shown in FIGS. 1 and 2, each of the thin film transistors 131 includes a gate electrode 124, a gate insulating layer 140, an active member 157, ohmic contacts 159, a source electrode 153, and a drain electrode 155.

The gate electrodes 124 are connected to the gate wires 121. The gate insulating layer 140 is formed on the gate electrodes 124 and has contact holes 163 also penetrating the passivation layer 161 exposing end portions 129 of the gate wires 121.

The active members 157 are disposed on the gate insulating layer 140 and overlap the gate electrodes 124. The active members 157 are insulated from the gate electrodes 124 by the gate insulating layer 140. The active members 157 form channels between the source electrodes 153 and the drain electrodes 155. The active members 157 may be formed of amorphous silicon.

The ohmic contacts 159 are formed on the active members 157. One pair of ohmic contacts 159 respectively form in an overlapping region of the active member 157 and the source electrode 153, and an overlapping region of the active member 157 and the drain electrode 155. The ohmic contacts 159 reduce the contact resistance between the active members 157 and the source electrodes 153 and between the active members 157 and the drain electrodes 155 to improve the transistor characteristics.

Each of the source electrodes 153 overlaps one portion of an active member 157. An end portion of each source electrode 153 is connected to a data wire 151. Accordingly, the source electrodes 153 are supplied with the pixel signals transmitted from the data wires 151. The pixel signals are transmitted to the drain electrode 155 through the channels formed in the active members 157 during a time in which the scanning signals are applied to the gate electrodes 124.

The drain electrodes 155 and the source electrodes 153 are disposed to be opposite to each other. A portion of each drain electrode 155 overlaps another portion of the active member 157. Because the display device, according to the present exemplary embodiment, comprises a transflective type of LCD, the pixel area includes a reflection area (RA) and a transmission area (TA), and the drain electrodes 155 are expanded to the center portion of the pixel area such that the drain electrodes 175 covers the entire reflection area RA, as shown in FIG. 1. Although the opaque drain electrodes 155 are widely disposed on the entire reflection region RA, it may not matter since the light is blocked in the reflection region RA.

The passivation layer 161 is formed on and protects the data wires 151 and the channel regions of the active members 157. The passivation layer 161 has contact holes 165 exposing end portions 156 of the data wires 151, and the passivation layer 161 and the gate insulating layer 140 have contact holes 163 exposing the end portions 129 of the gate wires 121.

The imprint layer 171 is formed on the passivation layer 161 and protects the thin film transistors 131. The imprint layer 171 may not exist in the transmission region TA and at an area around the contact holes 163 and 165, and an optical pattern OP may be formed on the whole surface of the imprint layer 171. The optical pattern OP improves reflection efficiency in the reflection region RA.

In the present exemplary embodiment, the optical pattern OP includes shapes of a plurality of concave mirrors, as shown in FIG. 2. Although various embossed shapes such as the convex mirror or a wave shape are examples of the optical pattern OP, the shape of the concave mirrors may optimally improve reflection efficiency. On the other hand, the concave mirror shape may be bilaterally dissymmetrical, which may improve the viewing angle in the reflection mode in this case.

The reflecting electrodes 181 that reflect external light are formed on the imprint layer 171, and are disposed in the reflection region RA. The planar boundaries of the reflecting electrodes 181 are coincident with those of the imprint layer 171, and the shape of the optical pattern OP is transcribed to the reflecting electrodes 181. The reflecting electrodes 181 may be formed of a metal material having excellent reflectance.

In the present exemplary embodiment, the reflecting electrodes 181 are disposed directly on the imprint layers 171, and a thin film for the reflecting electrodes 181 is deposited right after the formation of the optical pattern OP of the imprint layer 171 without a process such as an etching step etc. in the manufacturing process. As such, the original shape of the optical pattern OP may be transcribed to the reflecting electrodes 181. On the other hand, in the present exemplary embodiment, the contact holes 173 penetrate the reflecting electrodes 181, the imprint layers 171, and the passivation layer 161. The contact holes 173 expose portions of the drain electrodes 155.

The pixel electrodes 191 are formed on the reflecting electrodes 181 and connected to the drain electrodes 155 through the contact holes 173. The pixel electrodes 191 generate an electric field along with a common electrode (not shown), which is separately provided, when the thin film transistor array panel, according to the present exemplary embodiment, is used in the display device. As shown in FIGS. 1 and 2, the pixel electrodes 191 may cover the whole area of the reflection region RA in the present exemplary embodiment. In other words, since the reflecting electrodes 181 may occupy the whole area of the reflection region RA, the reflecting electrodes 181 and the pixel electrodes 191 overlap each other in the reflection region RA, while there are only the pixel electrodes 191 in the transmission region TA.

The contact assistants 81 and 82 are disposed on the passivation layer 161, and are connected to the end portions 156 and 129 of the gate wires 121 and the data wires 151 through the contact holes 163 and 165. The contact assistants 81 and 82 enhance the connections between the wires 121 and 151 and the external circuits, and protect them.

As shown in FIGS. 1 and 2, the thin film transistor array panel, according to the present exemplary embodiment, includes storage electrodes 125. The storage electrodes 125 receive a storage voltage from storage wires 123 that extend substantially parallel to the gate wires 121. In the present exemplary embodiment, the storage electrodes 125 overlap the drain electrodes 155 to form storage capacitors. The storage capacitors stabilize the pixel voltages applied to the pixel electrodes 191 and the reflecting electrodes 181.

As shown in FIGS. 1 and 2, the drain electrodes 155 and the storage electrodes 125 are disposed in the opaque reflection region RA, and their areas may be widely extended over the whole region of the reflection area RA. In one aspect, it increases the capacitance of the storage capacitors such that the pixel voltages may be stably maintained, and a reduction of the aperture ratio due to an increase of the areas of the drain electrodes 155 and the storage electrodes 125 may be prevented.

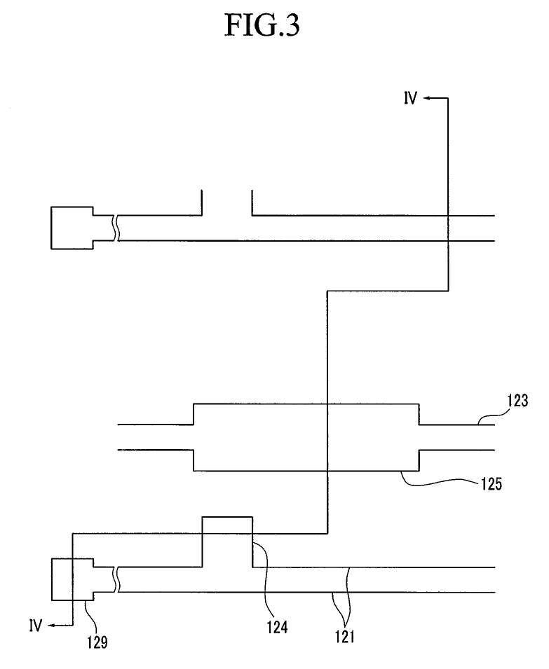

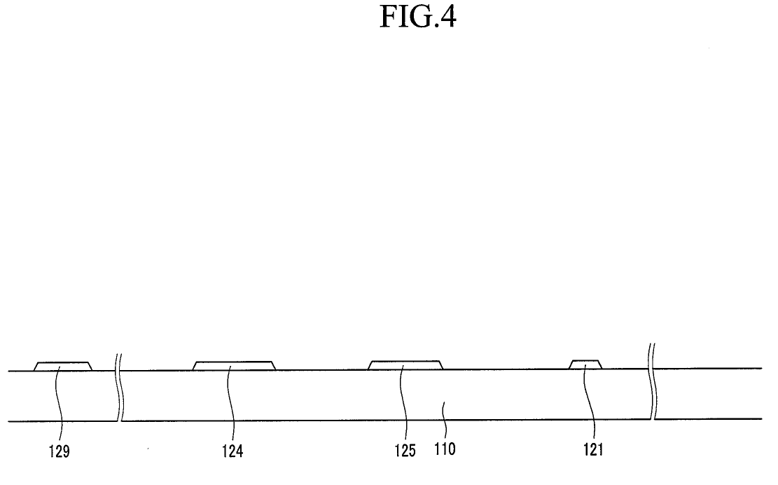

A manufacturing method of the thin film transistor array panel shown in FIGS. 1 and 2 will be described in reference to FIGS. 3 to 19. In particular, FIG. 3 is a layout view of the thin film transistor array panel in an intermediate process of manufacturing the thin film transistor array panel shown in FIGS. 1 and 2 according to an exemplary embodiment of the present disclosure, and FIG. 4 is a cross-sectional view of the thin film transistor array panel shown in FIG. 3 taken along the line IV-IV.

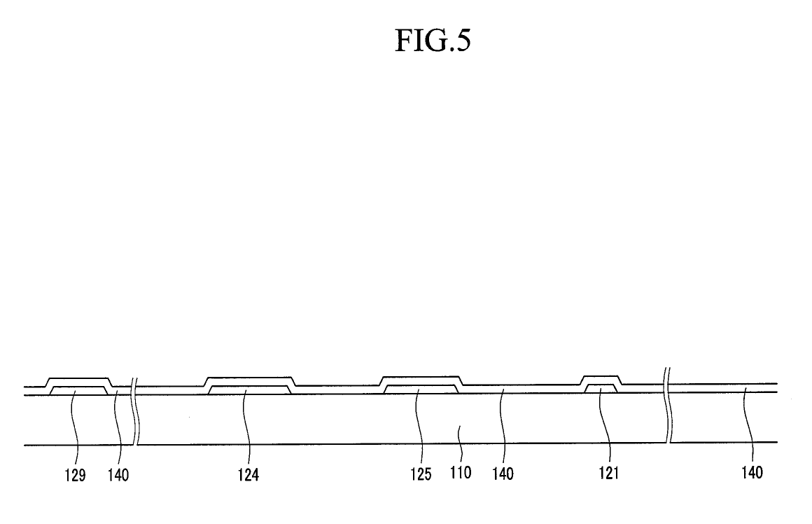

A gate conductor including gate wires 121, gate electrodes 124, storage wires 123, and storage electrodes 125 is formed on a substrate 110 through a first mask process. In one implementation, a gate metal layer (not shown) may be deposited on the substrate 110 through a deposition method such as sputtering. The gate metal layer is a single layer or multi-layer that is made of a metal such as Mo, Ti, Cu, Al, Nd, Al, Cr, a Mo alloy, a Cu alloy, or an Al alloy. Next, the gate metal layer is patterned through a photolithography process and an etching process using the first mask to form the gate conductor including the gate wires 121, the gate electrodes 124, the storage wires 123, and the storage electrodes 125. Next, as shown in FIG. 5, a gate insulating layer 140 is deposited on the substrate 110, the gate wires 121, the gate electrodes 124, and the storage wires 123. The gate insulating layer 140 may be made of an inorganic insulating material such as silicon oxide (SiOx) or silicon nitride (SiNx).

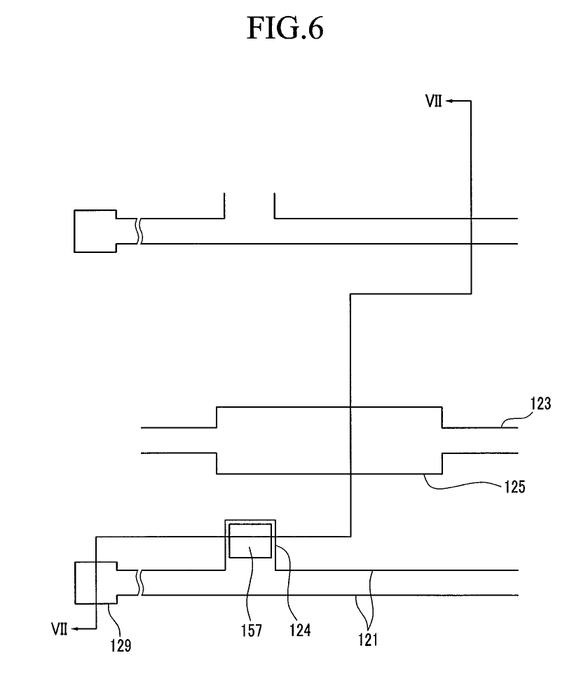

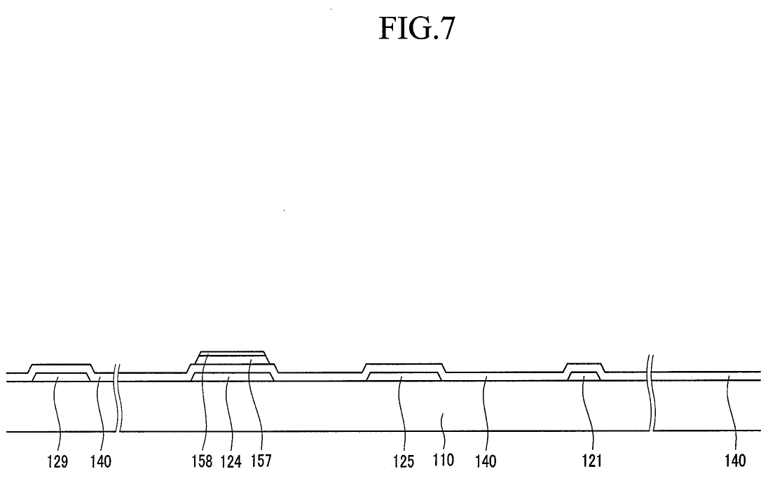

FIG. 6 is a layout view for explaining a process using a second mask in the manufacturing method of the thin film transistor array panel according to an exemplary embodiment of the present disclosure, and FIG. 7 is a cross-sectional view of the thin film transistor array panel shown in FIG. 6 taken along the line VII-VII.

In one embodiment, active members 157 and extrinsic semiconductor members 158 are formed on the gate insulating layer 140 using a second mask process. In one implementation, an intrinsic amorphous silicon layer (not shown) and an extrinsic amorphous silicon layer (not shown) doped with an impurity (n+ or p+) are sequentially deposited on the gate insulating layer 140. For example, the intrinsic amorphous silicon layer and the extrinsic amorphous silicon layer are formed by PECVD (plasma enhanced chemical vapor deposition). Next, a photoresist (not shown) is coated on the extrinsic amorphous silicon layer, and the extrinsic amorphous silicon layer and the amorphous silicon layer are patterned by photolithography and etching with the second mask to form the extrinsic semiconductor members 158 and the active members 157.

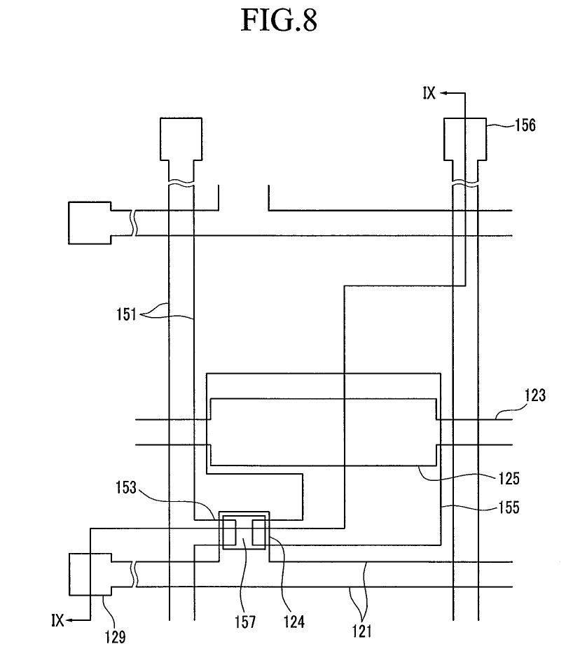

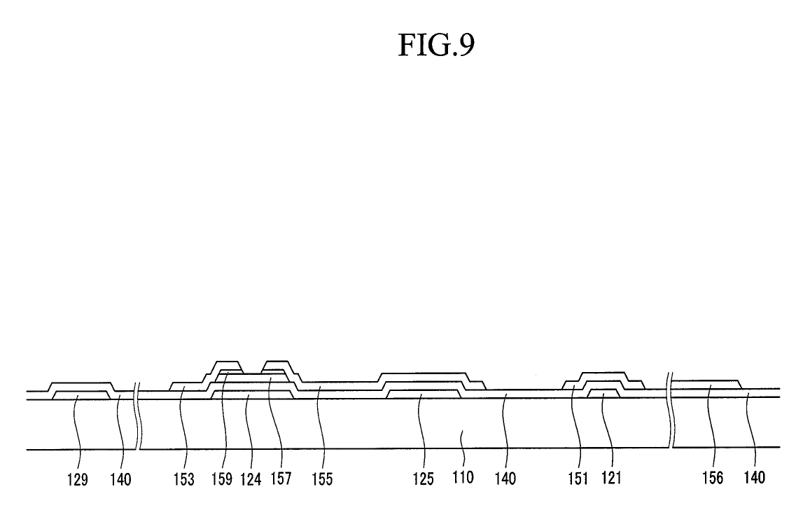

FIG. 8 is a layout view for explaining a process using a third mask in the manufacturing method of the thin film transistor array panel according to an exemplary embodiment of the present disclosure, and FIG. 9 is a cross-sectional view of the thin film transistor array panel shown in FIG. 8 taken along the line IX-IX.

In one embodiment, a source-drain conductor including data wires 151, source electrodes 153, and drain electrodes 155 is formed on the substrate 110 including the semiconductor members through the process using a third mask. In one implementation, a source-drain metal layer is deposited on the substrate 110 on which the semiconductor members are formed. For example, the source-drain metal layer may be formed through sputtering. The source-drain metal layer (not shown) may have a single-layered structure or a multi-layered structure including a metal such as Mo, Ti, Cu, Al, Nd, Al, Cr, a Mo alloy, a Cu alloy, or an Al alloy. Next, a photoresist (not shown) is coated on the source-drain metal layer and then the source-drain metal layer is patterned by photolithography and etching with the third mask to form the source-drain conductor including the data wires 151, the source electrodes 153, and the drain electrodes 155. After patterning the source-drain metal layer, exposed portions of the extrinsic semiconductor members 158 disposed between the source electrodes 153 and the drain electrodes 155 are removed to form ohmic contacts 159. Accordingly, in one example, as shown in FIG. 9, the ohmic contacts 159 remain only under the source electrodes 153 and the drain electrodes 155 to form semiconductor members along with the active members 157. On the other hand, while the semiconductor members and the source-drain conductors may be formed by using separate masks as described above, they may alternatively be formed by using a single mask such as a slit mask or a half tone mask. When forming the semiconductor member and the source-drain conductor with one mask, the number of the masks may be reduced.

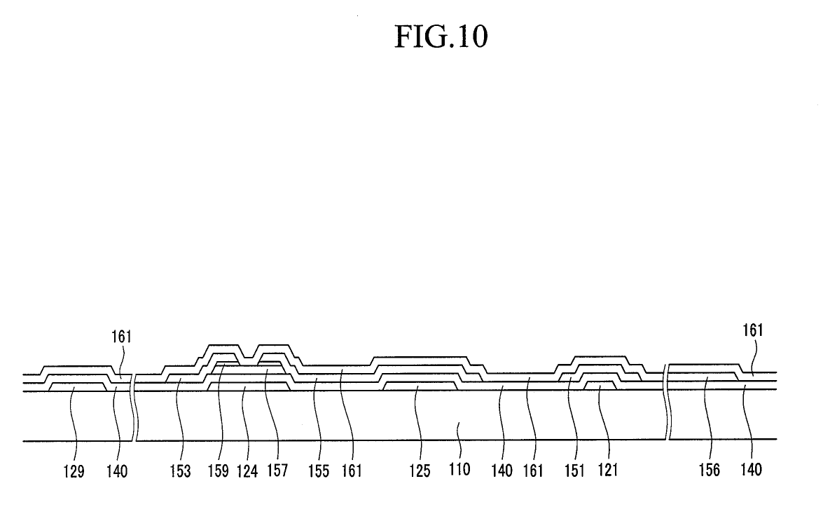

FIG. 10 is a cross-sectional view showing a process for forming a passivation layer 161 in the manufacturing method of the thin film transistor array panel according to an exemplary embodiment of the present disclosure. As shown in FIG. 10, a passivation layer 161 is deposited on the substrate 110 having the source-drain conductor. The passivation layer 161 may be made of an inorganic insulating material such as silicon oxide (SiOx) or silicon nitride (SiNx).

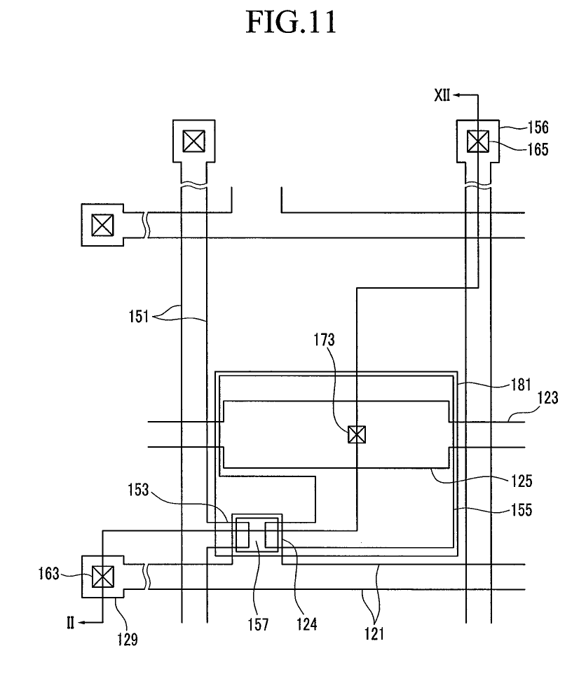

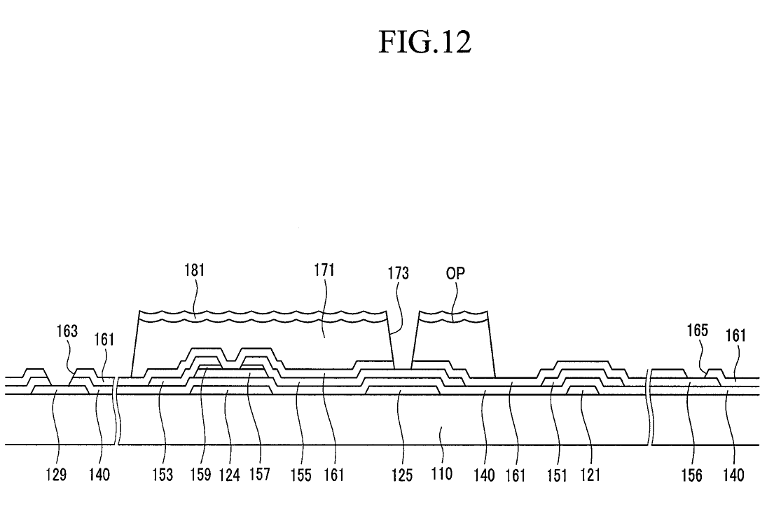

FIG. 11 is a layout view explaining the process for forming a reflecting electrode in the manufacturing method of the thin film transistor array panel according to an exemplary embodiment of the present disclosure, and FIG. 12 is a cross-sectional view of the thin film transistor array panel shown in FIG. 11 taken the line XII-XII.

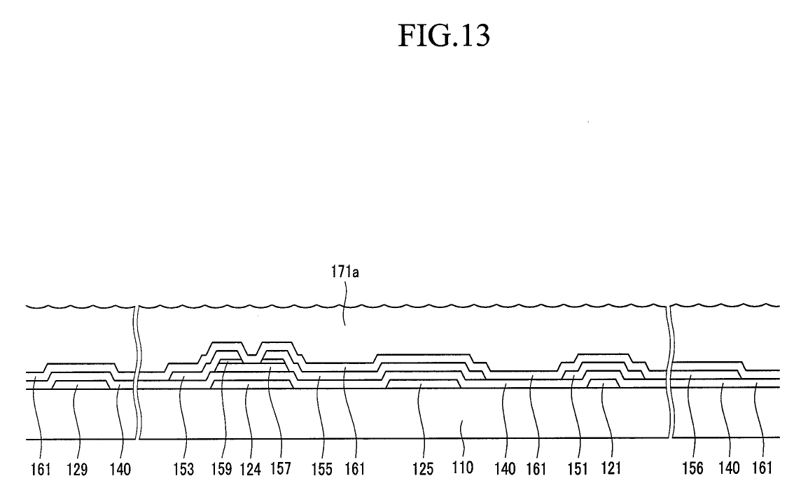

FIGS. 13 to 19 are cross-sectional views sequentially illustrating the immediate processes in the manufacturing method of the thin film transistor array panel shown in FIGS. 11 and 12 according to the present exemplary embodiment. In one implementation, an organic layer 171 a is coated on the substrate 110 on which the passivation layer 161 is formed. It may be preferable that the surface of the organic layer 171a has a uniform height. Then, the organic layer 171a is imprinted with a mold (not shown) such that an optical pattern of a desired shape is formed on the surface of the organic layer 171a. The surface shape of the organic layer 171a may particularly be an embossing (or embossed) shape such as a concave mirror shape or a dissymmetrical shape. Then, a reflection electrode layer 181a is deposited on the organic layer 171a. As an example, the reflecting electrode layer 181a is formed by sputtering a metal layer such as Al or an Al alloy.

In the present exemplary embodiment, the reflecting electrode layer 181a is deposited right after the imprint process without additional process for treating the organic layer 171a. As such, the optical pattern formed on the organic layer 171a through the imprint process is completely transcribed to the reflecting electrode layer 181a without any damage.

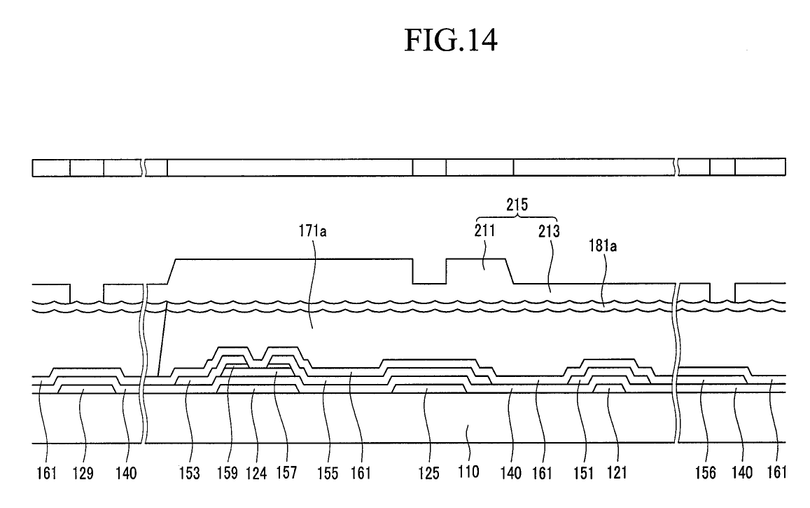

As shown in FIG. 14, a photosensitive film 215 is formed on the reflecting electrode layer 181a. The photosensitive film 215 includes a first portion 211 and a second portion 213. The first portion 211 is disposed on the reflection region RA. The second portion 213 is disposed on the transmission region TA and is thicker than the first portion 211. In one implementation, the photosensitive film 215 may not exist on the portions of the drain electrode 155, the gate lines 121, and the data lines 171. For descriptive convenience, portions of the reflecting electrode layer 181a, the organic layer 171a, the passivation layer 161, and the gate insulating layer 140, which are disposed under the first portion 211 of the photosensitive film 215, are referred to as first portions. Similarly, portions of the reflecting electrode layer 181a, the organic layer 171a, the passivation layer 161, and the gate insulating layer 140, which are disposed under the second portions 213 of the photosensitive film 215, are referred to as second portions. In one implementation, a portion of the reflecting electrode layer 181a, which is not covered by the photosensitive film 215 to be exposed, and portions of the organic layer 171a, the passivation layer 161, and the gate insulating layer 140, which are disposed under the exposed portions of the reflecting electrode layer 181a, are referred to as third portions.

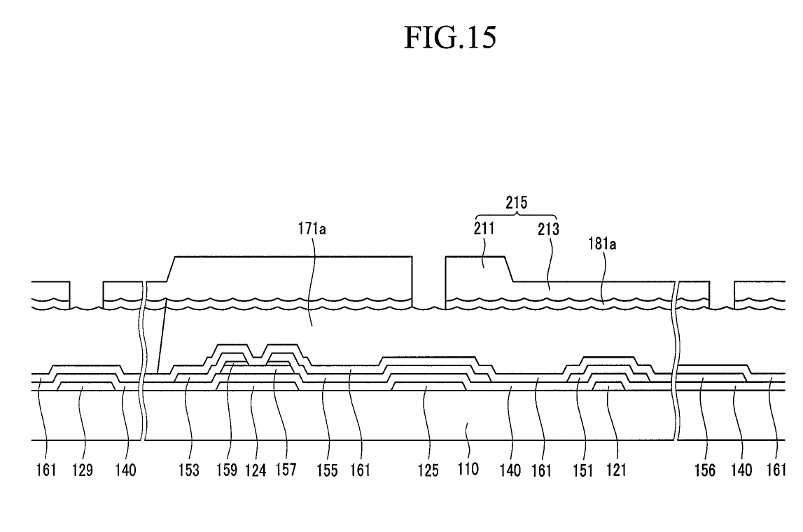

Next, as shown in FIG. 15, the third portion of the reflecting electrode layer 181a that are not covered by the photosensitive film 215 is removed. Dry etching may be used as the removal method.

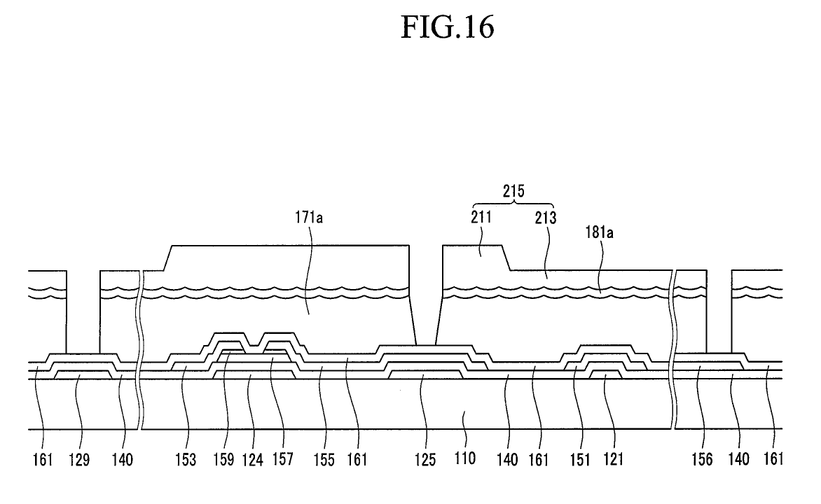

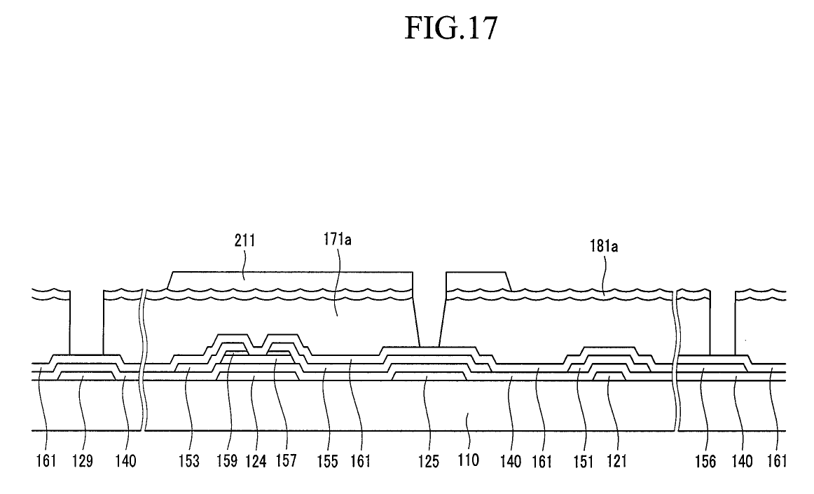

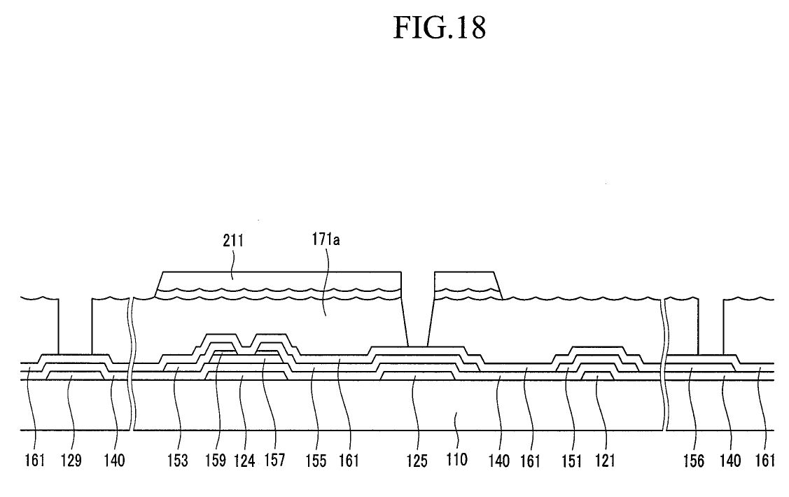

Then, as shown in FIG. 16, the third portion of the organic layer 171a is removed by dry etching or ashing to expose the third portion of the passivation layer 161. As shown in FIG. 17, the second portion 213 of the photosensitive film 215 is then removed by an etch-back process such that only the first portion 211 remains. Then, as shown in FIG. 18, the second portion of the reflecting electrode layer 181a that is exposed by removing the second portion 213 of the photosensitive film 215 is then removed by using dry etching.

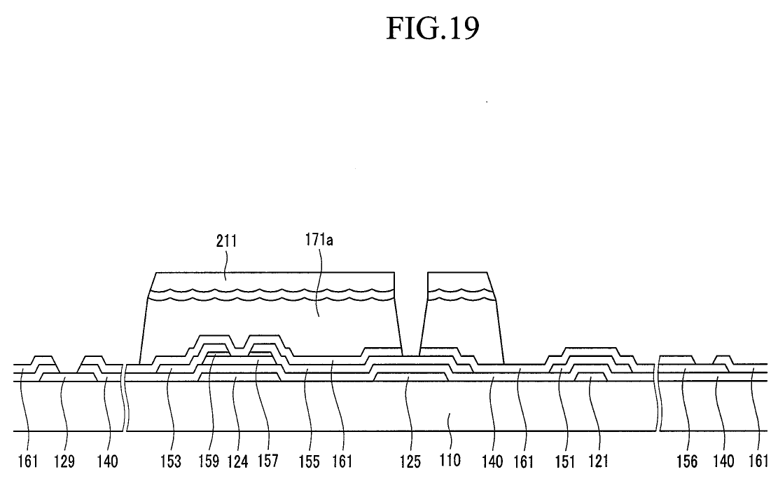

As shown in FIG. 19, the second portion of the organic layer 171a is removed to expose the surface of the second portion of the passivation layer 161, and simultaneously, the third portions of the passivation layer 161 and the gate insulating layer 140 are removed to form contact holes 163, 165, and 173. However, a portion disposed under the source-drain conductor among the third portion of the gate insulating layer 140 is not removed.

In one example of the detailed etching method, the organic layer 171a, the passivation layer 161, and the gate insulating layer 140 may be simultaneously etched under one condition. In this case, the etch condition may be appropriately controlled to match a first time when the contact holes 163, 165, and 173 are completed to expose portions of the gate lines 121 and the source-drain conductors are exposed thereunder with a second time when the removal of the second portion of the organic layer 171a is completed such that the second portion of the passivation layer 161 is exposed thereunder, or to allow the second time to be longer than the first time. Here, the second time becomes an etching ending time. According to the condition, the thickness of the second portion of the passivation layer 161 may be reduced.

In another example of the etching method, a condition in which the organic layer 171a, the passivation layer 161, and the gate insulating layer 140 are selectively etched may be used. In this case, the condition in which only the passivation layer 161 and the gate insulating layer 140 are etched and the organic layer 171a is not etched is used, such that firstly the third portions of the passivation layer 161 and the gate insulating layer 140 are removed to complete the contact hole 163, 165, and 173. Next, the condition in which the organic layer 171a is etched and the passivation layer 161 is not etched is used such that the second portion of the organic layer 171a may be removed. The remaining first portion 211 may then be removed to complete the imprint layer 171 and the reflecting electrode 181. Next, pixel electrodes 191 are formed on the substrate 110 including the reflecting electrode 181 through a process using a fourth mask.

In one implementation, a transparent conductor layer is deposited on the substrate 110 having the reflecting electrodes 181 by sputtering. The transparent conductor layer may be made of a material such as indium tin oxide (ITO), tin oxide (TO), indium zinc oxide (IZO), SnO₂, or amorphous-indium tin oxide (a-ITO). Next, the transparent conductor layer is patterned by photolithography and etching to form the pixel electrodes 191.

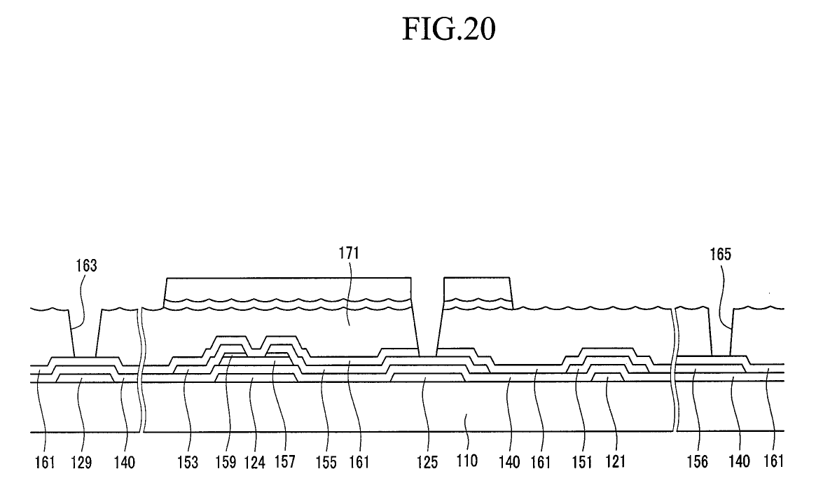

A thin film transistor array panel and a manufacturing method thereof according to another exemplary embodiment of the present disclosure will be described with reference to FIGS. 20 to 22. In particular, FIGS. 20 to 22 are cross-sectional views of a thin film transistor array panel in the manufacturing method of the thin film transistor array panel according to another exemplary embodiment of the present disclosure.

The present exemplary embodiment is similar to the above-described embodiment, and the same reference numerals as used in the above-described embodiment refer to the same constituent elements in FIGS. 20 to 22 and descriptions thereof are not repeated.

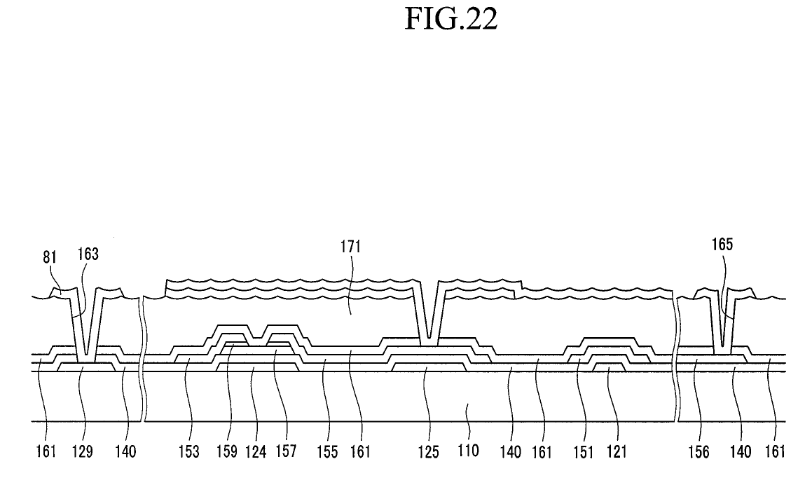

As shown in FIG. 22, an imprint layer 171 may be formed in the transmission region TA in the present exemplary embodiment, which is different from the previous embodiment. The imprint layer 171 is disposed on the end portions 129 of the gate wires 121 and the end portions 156 of the data wires 151, contact holes 163 pass through the imprint layer 171 as well as the passivation layer 161 and the gate insulating layer 140, and contact holes 165 pass through the passivation layer 161 and the imprint layer 171.

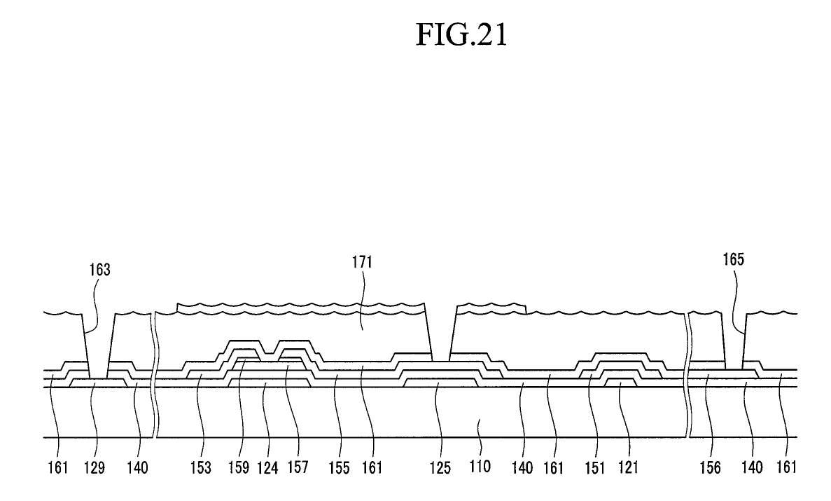

To manufacture this structure, after forming the reflecting electrodes 181 as shown in FIG. 20 corresponding to FIG. 18 of the previous exemplary embodiment, the passivation layer 161 and the gate insulating layer 140 may be selectively etched, as shown in FIG. 21. In the case of the etch condition for etching all of the organic layer 171a, the passivation layer 161, and the gate insulating layer 140, if the time at which the contact holes 163 and 165 are completed and the end portions 129 and 156 of the data wires 151 and the gate wires 121 are exposed is determined as the etching ending time, the organic layer 171a still remains although the thickness of the organic layer 171a is reduced.

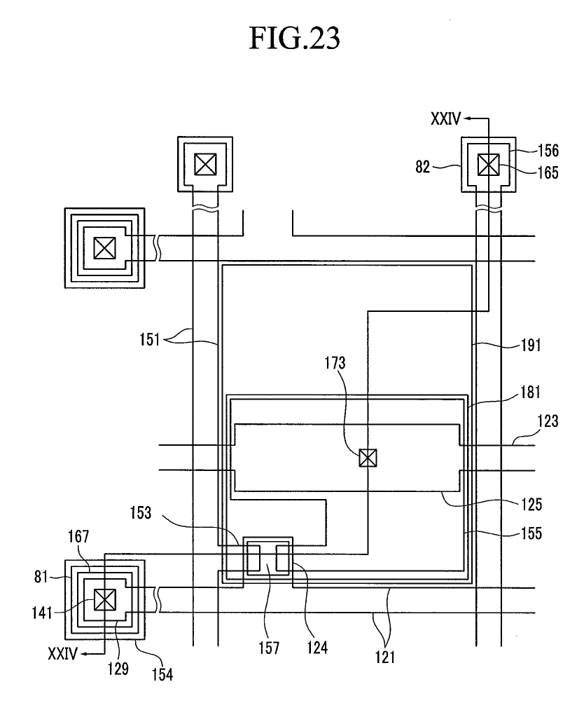

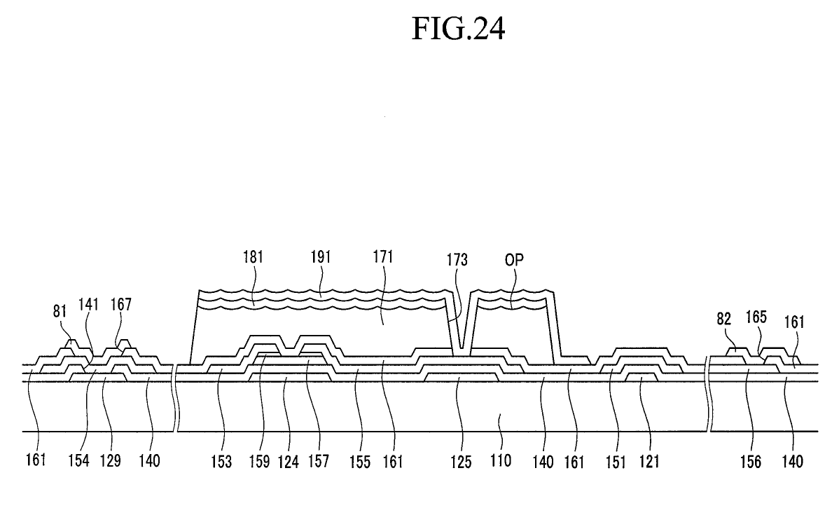

Next, a thin film transistor array panel according to another embodiment of the present disclosure will be described in detail with reference to FIGS. 23 and 24. In particular, FIG. 23 is a layout view of a thin film transistor array panel according to another embodiment of the present disclosure, and FIG. 24 is a cross-sectional view of the thin film transistor array panel shown in FIG. 23 taken along the line XXIV-XXIV.

As shown in FIGS. 23 and 24, the structure of the thin film transistor array panel according to the present exemplary embodiment is similar to that of FIGS. 1 and 2. That is to say, the thin film transistor array panel includes substrate 110, gate wires 121, data wires 151, storage electrodes 125, storage wires 123, thin film transistors 131, passivation layer 161, reflecting electrodes 181, pixel electrodes 191, contact assistants 81 and 82, and imprint layers 171. The thin film transistors 131 include gate electrodes 124, a gate insulating layer 140, active members 157, ohmic contacts 159, source electrodes 153, and drain electrodes 155. The reflecting electrodes 181, the imprint layers 171, and the passivation layer 161 have contact holes 173, and the passivation layer 161 has contact holes 165 exposing the end portions 156 of the data wires 151.

However, in contrast to the discussion in reference to FIGS. 1 and 2, the gate insulating layer 140 has contact holes 141 exposing the end portions 129 of the gate wires 121, and contact agency members 154 are formed thereon. The contact agency members 154 are formed with the same layer as the data wires 151 and then covered by the passivation layer 161, but the passivation layer 161 has contact holes 167 exposing portions of the contact agency members 154. The contact agency members 154 are connected to the contact assistants 81 through the contact holes 167 and covered by the contact assistants 81.

In one aspect, it should be appreciated that the manufacturing method of the thin film transistor array panel may be similar to FIGS. 3 to 19, but because a photolithography process for forming the contact holes 141 is required after depositing the gate insulating layer 140, one additional photolithography etching process is necessary in comparison with the manufacturing method of FIGS. 3 to 19. However, because the gate insulating layer 140 is not etched in the step of FIG. 19, the etching time may be reduced, and damage to portions of the drain electrodes 155, the end portions 156 of the data wires 151, and the organic layer 171a, which are exposed after etching the passivation layer 161 may be reduced.

Accordingly, in the thin film transistor array panel according to an embodiment of the present disclosure, because the optical pattern is disposed on the whole surface of the display panel when forming a reflecting electrode through an imprint process, it is not necessary to only align an imprint mold on the reflection region, thereby reducing the manufacturing process time. Moreover, because the imprint mold is manufactured with a size corresponding to the whole surface of the display panel restriction to regardless of the size of the reflection region, the manufacturing cost of the imprint mold may be reduced.

It should be appreciated that the above-described embodiments of the present disclosure may be applied to a reflective LCD having no transmission region, as well as to the transflective LCD.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A thin film transistor array panel comprising:
a gate wire;
a data wire intersecting the gate wire;
a thin film transistor connected to the gate wire and the data wire;
an imprint layer disposed on the gate wire, the data wire, and the thin film transistor, the imprint layer having a contact hole exposing a portion of the thin film transistor;
a reflecting electrode disposed on the imprint layer, the reflecting electrode having planar boundaries substantially matching with planar boundaries of the imprint layer or having narrower planar boundaries than the imprint layer; and
a pixel electrode comprising a first portion disposed on the reflecting electrode,
wherein the pixel electrode is connected to the thin film transistor through the contact hole.

2. The thin film transistor array panel of claim 1, further comprising a passivation layer disposed between the thin film transistor and the imprint layer.

3. The thin film transistor array panel of claim 1, wherein the imprint layer has an upper surface provided with an optical pattern.

4. The thin film transistor array panel of claim 3, wherein the optical pattern comprises an embossed shape.

5. The thin film transistor array panel of claim 4, wherein the embossed shape comprises a concave mirror shape.

6. The thin film transistor array panel of claim 1, wherein the pixel electrode comprises a second portion that does not overlap the reflecting electrode.

7. The thin film transistor array panel of claim 6, wherein the imprint layer comprises a portion disposed under the second portion of the pixel electrode.

8. The thin film transistor array panel of claim 6, wherein the thin film transistor comprises a drain electrode connected to the pixel electrode, and wherein the thin film transistor array panel further comprises a storage electrode overlapping the drain electrode.

9. The thin film transistor array panel of claim 8, wherein the storage electrode overlaps the reflecting electrode.

10. A method for manufacturing a thin film transistor array panel, comprising:
forming a gate wire, a data wire, and a thin film transistor on a substrate;
depositing an organic material layer on the gate wire, the data wire, and the thin film transistor;
forming an optical pattern on an upper surface of the organic material layer;
depositing a reflecting electrode layer on the organic material layer;
etching the reflecting electrode layer;
etching the organic material layer after etching the reflecting electrode layer; and
forming a pixel electrode on the reflecting electrode layer.

11. The method of claim 10, wherein the pixel electrode comprises a first portion overlapping the reflecting electrode and a second portion not overlapping the reflecting electrode.

12. The method of claim 11, wherein the organic material layer is disposed under the first and second portions of the pixel electrode.

13. The method of claim 10, further comprising forming a passivation layer on the gate wire, the data wire, and the thin film transistor, and under the organic material layer.

14. The method of claim 10, wherein the organic material layer is etched to have substantially the same planar shape as the reflecting electrode.

15. The method of claim 10, wherein the etching of the reflecting electrode layer and the etching of the organic material layer are executed by a single photolithography step.

16. The method of claim 10, wherein the forming of the optical pattern comprises:
aligning an imprint mold on the organic material layer; and
imprinting the organic material layer with the imprint mold.
